(19) United States
(12) Patent Application Publication
(10) Pub. No.: US 2026/0081089 A1
(43) Pub. Date: Mar. 19, 2026

(54) BACKEND FIELD EMISSION DEVICES

(71) Applicants: Abhishek A. Sharma, Portland, OR (US); Wilfred Gomes, Portland, OR (US); Tahir Ghani, Portland, OR (US)

(72) Inventors: Abhishek A. Sharma, Portland, OR (US); Wilfred Gomes, Portland, OR (US); Tahir Ghani, Portland, OR (US)

(21) Appl. No.: 18/888,282

(22) Filed: Sep. 18, 2024

(51) Int. Cl. H01J 1/304

(52) U.S. Cl. CPC H01J 1/3044; H01J 2201/30411; H01J 2201/30449; H01J 2201/319

(57) ABSTRACT

A backend field emission device may include a field emission device in a backend of line (BEOL) layer, such as an interconnect layer. In one example, a backend field emission device includes a first electrode coupled with a first conductive interconnect, a second electrode coupled with a second conductive interconnect, an airgap between the first electrode and the second electrode, and a third electrode between the first electrode and the second electrode and coplanar with the airgap.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of an integrated circuit (IC) structure including backend field emission devices, in accordance with various embodiments.

FIGS. 2A-2B are cross-sectional side views of examples of backend field emission devices, in accordance with embodiments disclosed herein.

FIGS. 3A-3E are different cross-sectional views of examples of IC structures including backend field emission devices, in accordance with embodiments disclosed herein.

FIG. 4 is a flow diagram of an example method for fabricating an IC structure including backend field emission devices, in accordance with some embodiments.

FIGS. 5A-5J provide cross-sectional side views at various stages in the fabrication of an example IC structure according to the method of FIG. 4, in accordance with some embodiments.

FIG. 6 is a flow diagram of an example method for fabricating an IC structure including backend field emission devices, in accordance with some embodiments.

FIGS. 7, 8A-8C, 9A-9C, 10A-10C, 11A-11C, 12A-12C, and 13A-13C provide cross-sectional side views at various stages in the fabrication of an example IC structure according to the method of FIG. 6, in accordance with some embodiments.

FIG. 14 is a top view of a wafer and dies that may include any of the IC structures disclosed herein, in accordance with any of the embodiments disclosed herein.

FIG. 15 is a side, cross-sectional view of an IC package that may include any of the IC structures disclosed herein, in accordance with various embodiments.

FIG. 16 is a side, cross-sectional view of an IC device assembly that may include any of the IC structures disclosed herein, in accordance with any of the embodiments disclosed herein.

FIG. 17 is a block diagram of an example electrical device that may include any of the IC structures disclosed herein, in accordance with any of the embodiments disclosed herein.

### DETAILED DESCRIPTION

### Disclosed Herein Are Integrated Circuit (IC) Structures Including backend field emission devices.

IC fabrication usually includes two stages. The first stage is referred to as the front-end of line (FEOL). The second stage is referred to as the back-end of line (BEOL). In the FEOL, individual semiconductor devices components (e.g., transistors, capacitors, resistors, etc.) can be patterned in a wafer. In the BEOL, interconnect structures such as conductive lines and conductive vias, separated as needed by an insulator material, can be formed form interconnections amongst individual components. The BEOL usually starts with forming the first metal layer on the wafer. The first metal layer is often called M0. More metal layers can be formed on top of M0, and these metal layers are often called M1, M2, and so on.

Metal layers may experience noise, which typically refers to unwanted electrical interference caused by the proximity of metal interconnects in ICs. This phenomenon occurs when electrical signals in one metal line induce voltages or currents in nearby lines through capacitive coupling, potentially leading to signal distortion, crosstalk, and degraded circuit performance. The effect becomes more pronounced as circuit densities increase and line spacings decrease. Operation of ICs at low temperatures may further exacerbate noise issues. Noise in metallization stacks may be mitigated through techniques such as increasing line spacing and optimizing layout patterns to minimize coupling. However, these mitigation strategies often come with drawbacks such as increased chip area, higher manufacturing costs, and potential reductions in overall circuit performance.

In accordance with examples described herein, backend field emission devices integrated into the backend of an IC structure may reduce some of the issues caused by noise in a metallization stack. A field emission device is an electronic component that emits electrons from a solid surface into a vacuum under the influence of an electric field. It typically consists of a cathode or emitter electrode with a tip and an anode or collector electrode, where electrons are extracted from the cathode when a sufficiently high voltage is applied between the electrodes. Field emission devices are used in various applications, including electron microscopes, flat panel displays, and microwave amplifiers; however, existing field emission devices are typically large in size (e.g., having dimensions in the range of several centimeters) and fabricated on a substrate. In contrast, backend field emission devices in accordance with examples described herein are much smaller than conventional field emission devices, and may be integrated into a BEOL layer along an electrical pathway in an IC. In some examples, backend field emission devices may act as switches or high current transmission interconnect devices along a data transmission path.

In one example, an IC includes a device region, a first interconnect layer over the device region, where the first interconnect layer includes a first conductive interconnect, a second interconnect layer over the first interconnect layer, where the second interconnect layer includes a second conductive interconnect, and a field emission device between the first interconnect layer and the second interconnect layer. In one example, the field emission device includes a first electrode (e.g., one or an emitter or collector electrode) coupled with the first conductive interconnect, a second electrode (e.g., another of the emitter or collector electrode) coupled with the second conductive interconnect, an airgap between the first electrode and the second electrode, and a third electrode (e.g., a gate electrode) between the first electrode and the second electrode and coplanar with the airgap.

IC structures including backend field emission devices as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies.

Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures including backend field emission devices as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

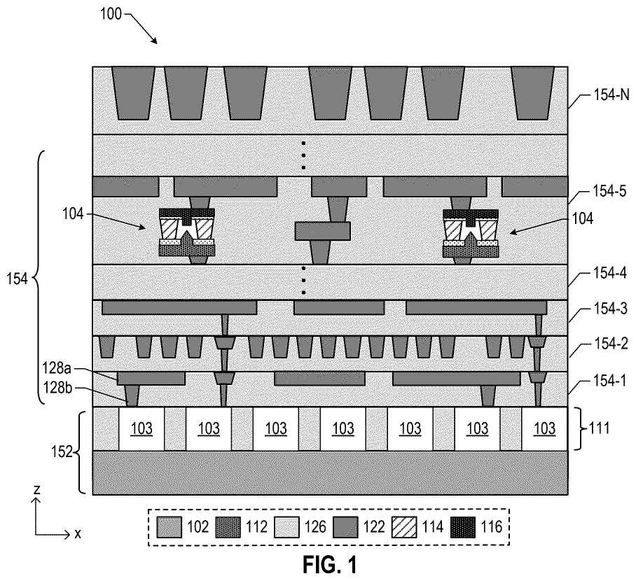

A number of elements referred to in the description of FIGS. 1, 2A-2B, 3A-3E, 5A-5J, 7, 8A-8C, 9A-9C, 10A-10C, 11A-11C, 12A-12C, and 13A-13C with reference numerals are illustrated in these drawings with different patterns, with a legend showing the correspondence between the reference numerals and patterns being provided at the bottom of each drawing page containing FIGS. 1, 2A-2B, 3A-3E, 5A-5J, 7, 8A-8C, 9A-9C, 10A-10C, 11A-11C, 12A-12C, and 13A-13C. For example, the legend illustrates that FIG. 1 uses different patterns to show a substrate 102, a conductive interconnect 122, and so on.

FIG. 1 is a cross-sectional side view of an IC structure 100 including backend field emission devices, in accordance with various embodiments. The IC structure 100 includes FEOL layers 152 and BEOL layers 154. A FEOL layer refers to a layer formed in the FEOL, such as a device layer or device region. In the FEOL, individual semiconductor devices components (e.g., transistors, capacitors, resistors, etc.) can be patterned in a wafer. A BEOL layer refers to a layer formed in the BEOL, such as an interconnect layer (e.g., metal layer) of a metallization stack. In the BEOL, interconnect structures such as conductive lines and conductive vias, separated as needed by an insulator material, can be formed to interconnect individual components. The BEOL usually starts with forming the first metal layer on the wafer. The first metal layer is often called M0. Additional metal layers can be formed on top of M0, and these metal layers are often called M1, M2, and so on.

In the example illustrated in FIG. 1, the FEOL layer 152 includes a device region 111 over a substrate 102. The substrate 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The device region 111 includes a plurality of devices 103. The devices 103 may be frontend devices (e.g., frontend transistors such as FinFETs, nanowire transistors, nanoribbon transistors, frontend memory cells, and/or other frontend devices). The devices 103 may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors. Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate-all-around” transistors).

The BEOL layers 154 may include a plurality of backend interconnects electrically coupled to (e.g., in electrically conductive contact with at least portions of) one or more of the plurality of FEOL devices of the FEOL layer 152. Various BEOL interconnect layers 154 may be/include one or more metal layers of a metallization stack of the IC device. Various metal layers of the BEOL interconnect layers 154 may be used to interconnect the various inputs and outputs of the devices (e.g., logic devices) in the FEOL layer 152. In one example, each of the BEOL interconnect layers 154 may include conductive interconnects 122, such as conductive vias and conductive lines/trenches. For example, the BEOL interconnect layer 154-1 includes a via portion 128b and a line or trench/interconnect portion 128a. The trench portion 128a of a metal layer is configured for transferring signals and power along electrically conductive (e.g., metal) lines (also sometimes referred to as “trenches”) extending in the x-y plane (e.g., in the x or y directions), while the via portion 128b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 154 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD) 126. Although the conductive interconnects are shown with the same shading, different conductive interconnects in different layers may be formed from different conductive materials. The insulating medium may include any suitable ILD materials such as silicon oxide, carbon-doped silicon oxide, silicon carbide, silicon nitride, aluminum oxide, and/or silicon oxynitride. In some embodiments, the ILD 126 disposed between the interconnect structures in different ones of the interconnect layers may have different compositions; in other embodiments, the composition of the ILD 126 between different interconnect layers may be the same. The example illustrated in FIG. 1 includes N interconnect layers (of which 154-1, 154-2, 154-3, 154-4, 154-5, and 154-N are shown), where N is a positive integer that is greater than 1. IC structures may include fewer or more interconnect layers than those shown in FIG. 1.

In the example illustrated in FIG. 1, the IC structure 100 includes backend field emission devices 104 in one or more of the BEOL layers 154. A field emission device 104 includes an emitter electrode 112, a collector electrode 116, an airgap between the emitter electrode 112 and the collector electrode 116 (where the airgap is represented by a white space between electrodes 112 and 116 in FIG. 1), and a gate electrode 114. A field emission device may be considered a “backend field emission device” due to its location in a BEOL layer. In some examples, the field emission devices 104 are coplanar with conductive interconnects in the layer in which the field emission devices 104 are located. In some examples, the backend field emission devices may be in higher up metal layers (e.g., M6, M7, M8, M9, M10, M11, M12, M13, M14, M15, GM0, GM1, etc., where “MX” represents the (X+1)th metal layer over the frontend device region 111, and “GMX” represents the (X+1)th global or giant metal layer). In some examples, the field emission devices 104 may be included in an electrical path as a switch and/or to improve transmission of signals. In some examples, when an appropriate bias is present across the emitter electrode 112 and collector electrode 116 (which may be controlled at least in part by a voltage applied to the gate electrode 114), emitter electrode 112 releases electrons, which are collected by the collector electrode 116. During emission, the field emission devices 104 may act almost like a short, conducting between the emitter electrode 112 and collector electrode 116. Thus, in some examples, the field emission devices 104 may provide high current switches in the backend, which may be turned on or off based on the voltage applied to the gate electrode 114. A conductive path can therefore be formed between conductive interconnects (e.g., conductive interconnects in layers below and over the field emission device 104) coupled with the emitter electrode 112 and collector electrode 116.

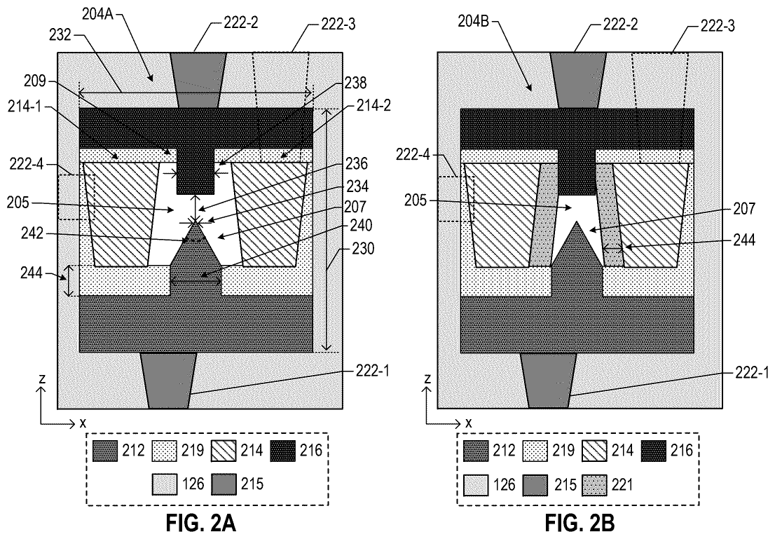

FIG. 2A-2B are cross-sectional side views of examples of backend field emission devices 204A and 204B. In accordance with examples, the backend field emission devices 204A and 204B may be in an interconnect layer over a device region (e.g., the device region 111 of FIG. 1). The backend field emission devices 204A and 204B each include a first electrode and a second electrode, where one of the first electrode and the second electrode is an emitter electrode, and another of the first electrode and the second electrode is a collector electrode. For example, the backend field emission devices 204A and 204B include an emitter electrode 212 (which may also be referred to as an emitter, an emitter element, an emission electrode, a cathode, or a cathode electrode) and a collector electrode 216 (which may also be referred to as a collector, collector element, anode, or anode electrode). In the example illustrated in FIGS. 2A-2B, the emitter electrode 212 is coupled with a first conductive interconnect 222-1, and the collector electrode 216 is coupled with a second conductive interconnect 222-2, where the first conductive interconnect 222-1 and the second conductive interconnect 222-2 include an electrically conductive material 215, such as those discussed above.

The emitter electrode 212 and the collector electrode 216 may include any suitable conductive materials. In one example, the emitter electrode 212 may and the collector electrode 216 may include materials that have different work functions. For example, the emitter electrode may include a first electrically conductive material with a first work function and the collector electrode 216 may include a second electrically conductive material with a second work function that is different (e.g., greater) than the first work function. In one such example, the difference between the first work function and the second work function may be in a range of about 0.2 to 2 eV. In one example, the emitter electrode 212 includes a conductive material with a relatively low work function (e.g., low relative to the work function of the collector electrode 216), such as one or more of: hafnium, zirconium, titanium, tantalum, aluminum, a conductive metal carbide (e.g., hafnium carbide, zirconium carbide, titanium carbide, tantalum carbide, and aluminum carbide), and molybdenum. In one example, the collector electrode 216 includes a conductive material with a relatively high work function (e.g., high relative to the work function of the emitter electrode 212), such as one or more of: ruthenium, palladium, platinum, cobalt, nickel, a conductive metal oxide (e.g., ruthenium oxide), titanium nitride, and tungsten. Other suitable electrically conductive materials are also possible for use in the emitter electrode 212 and the collector electrode 216.

The backend field emission devices 204A and 204B each include an airgap 205 between the emitter electrode 212 and the collector electrode 216. In one example, the airgap 205 may be a region that is devoid of solid material. The airgap 205 may include minimal or no material (e.g., the airgap 205 may be a vacuum or substantially a vacuum), or the airgap 205 may be filled with a gaseous substance, e.g., nitrogen gas or a different gas. The airgap 205 may also be referred to as a void. A portion 209 of the collector electrode 216 and a portion 207 of the emitter electrode 212 protrude towards one another across the airgap 205 and are substantially aligned with one another. In operation, if a sufficient bias is applied, electrons are emitted from the emitter electrode 212 into the airgap 205 and collected by the collector electrode 216, resulting in conduction of current from the emitter electrode 212 to the collector electrode 216.

The backend field emission devices 204A and 204B each also include a third electrode between the first electrode and the second electrode and coplanar with the airgap 205. For example, the backend field emission devices 204A and 204B each include the gate electrodes 214-1 and 214-2 (referred to herein as gate electrode(s) 214). The gate electrodes 214 may include any suitable electrically conductive material, e.g., a gate electrode material. In some examples, the gate electrodes 214 may include one or more of ruthenium, palladium, platinum, cobalt, nickel, and conductive metal oxides (e.g., ruthenium oxide), hafnium, zirconium, titanium, tantalum, aluminum, alloys of these metals, and carbides of these metals (e.g., hafnium carbide, zirconium carbide, titanium carbide, tantalum carbide, and aluminum carbide), copper, gold, cobalt, and tungsten. The gate electrodes 214 may be coupled with a third conductive interconnect to enable application of a voltage bias across the devices 204A, 204B. In one example, the gate electrode 214 may have a portion that protrudes along the y-axis (e.g., into or out of the page as shown in FIGS. 2A and 2B), to enable coupling with a via (e.g., such as the conductive interconnect 222-3, which is shown with a dotted line contour). In one example, a coplanar conductive line may coupled with the gate electrode 214 (e.g., such as the conductive interconnect 222-4, which is shown with a dotted contour). Thus, the gate electrode 214 may be used to actuate emission of electrons from the emitter electrode 212 towards the collector electrode 216.

In accordance with examples, the dimensions of the devices 204A and 204B may be in the range of hundreds of nanometers. For example, the height 230 of the devices 204A and 204B may be in a range of about 50 to 500 nanometers, about 75 to 200 nanometers, or about 90 to 120 nanometers (where the height is a dimension of the devices 204A, 204B in a plane substantially orthogonal to the device region, e.g., along the z-axis as shown in FIGS. 2A and 2B). In one example, the width 232 of the devices 204A and 204B may be in a range of about 50 to 500 nanometers, about 75 to 200 nanometers, or about 90 to 120 nanometers (where the width is a dimension of the devices 204A, 204B in a plane substantially parallel to the device region, e.g., along the x-axis as shown in FIGS. 2A and 2B). In one example, the emitter electrode 212 includes a tip portion 207 (e.g., a pointed tip) opposite the collector electrode 216, where the tip portion 207 has a first width 234 (e.g., a width or diameter of the tip) in a range of about 1 to 20 nanometers, about 1 to 10 nanometers, or about 1 to 6 nanometers (where the width 234 of the tip portion 207 is a dimension of the tip portion 207 in a plane substantially parallel to the device region, e.g., along the x-axis as shown in FIGS. 2A and 2B). A portion of the emitter electrode 212 further from the tip may have a greater width 240 (e.g., greater than the width 234), which may be in the range of about 5 to 25 nanometers, about 15 to 25 nanometers, or about 18 to 22 nanometers. In some examples, the collector electrode 216 may have a width 238 that is in a range of about 0.5 to 10 times the width 240 of the emitter electrode 212. Therefore, in some examples, the width 238 of collector electrode 216 may be greater than the width 240, about the same as the width 240, or smaller than the width 240. In other examples, the dimensions of the emitter electrode 212 and the collector electrode 216 may be different than the examples provided (e.g., the width 240 may be greater than 25 nanometers, etc.).

As can be seen in the examples in FIGS. 2A and 2B, the emitter electrode 212 has a pointed tip. For example, in the cross-section shown in FIGS. 2A and 2B, the tip portion 207 has a first side and a second side that meet at a tip (e.g., pointed tip), where the tip is a portion of the emitter electrode 212 is closest to the collector electrode 216. As can be seen in FIGS. 2A and 2B, the first side is at an angle 242 relative to the second side. In one such example, the angle is in a range of about 20-80 degrees, or about 30 to 60 degrees. In the example illustrated in FIGS. 2A and 2B, the cross-sectional shape of the tip portion 207 is substantially triangular; however, in other examples, the tip portion may have a different shape. For example, the sides of the tip portion 207 that meet at the tip may not be straight (e.g., the sides may be curved). As mentioned briefly above, the tip of the tip portion 207 may be the closest portion of the emitter electrode 212 to the collector electrode 216, which may also have a protruding portion opposite and substantially aligned with the tip portion 207 of the emitter electrode 212. In some examples, a distance 236 between the emitter electrode 212 and the collector electrode 216 may be in a range of about 5 to 50 nanometers, or about 10 to 30 nanometers.

In the example illustrated in FIGS. 2A and 2B, the backend field emission devices 204A and 204B each include two gate electrodes 214-1 and 214-2 on either side of the airgap 205. For example, the field emission device 204A includes a first gate electrode 214-1 and a second gate electrode 214-2 that is coplanar with the first gate electrode 214-1, where the airgap is between the first gate electrode 214-1 and the second gate electrode 214-2. In one example, the portions of the emitter electrode 212 and collector electrode 216 that are protruding towards one another in the airgap 205 are between the gate electrodes 214-1 and 214-2. In the example illustrated in FIGS. 2A and 2B an insulator material 219 may be present below the gate electrodes 214-1 and 214-2 (e.g., between the emitter electrode 212 and the gate electrode 214-1 and between the emitter electrode 212 and the gate electrode 214-2) and above the gate electrodes 214-1 and 214-2 (e.g., between the collector electrode 216 and the gate electrode 214-1 and between the collector electrode 216 and the gate electrode 214-2). In some examples, a thickness 244 of the insulator material 219 may be in a range of about 3 to 50 nanometers, or a range of about 3 to 20 nanometers, and may be any suitable insulator material (e.g., silicon oxide, silicon nitride, aluminum oxide, aluminum oxynitride, or any other suitable insulator material), where the thickness 244 is a dimension of the insulator material 219 in a plane that is substantially orthogonal to the device region. The thickness 244 of the insulator material 219 between the gate electrodes 214-1 and 214-2 and the emitter electrode 212 may be substantially the same as or different from the thickness of the insulator material 219 between the gate electrodes 214-1 and 214-2 and the collector electrode 216.

In the example illustrated in FIG. 2A, a portion of the airgap 205 may be present between the gate electrodes 214-1, 214-2 and the emitter electrode 212 and between the gate electrodes 214-1, 214-2 and the collector electrode 216 (e.g., there is not an intervening material between the gate electrode 214-1 and the protruding portions of the emitter electrode 212 and the collector electrode 216, and there is not an intervening material between the gate electrode 214-2 and the protruding portions of the emitter electrode 212 and the collector electrode 216). In contrast, in the example illustrated in FIG. 2B, the gate electrodes 214-1 and 214-2 are lined with a dielectric material 221. For example, in FIG. 2B, the dielectric material 221 is present between the gate electrode 214-1 and the airgap 205, and between the gate electrode 214-2 and the airgap 205. In other words, in the example cross-section shown in FIG. 2B, the airgap 205 is between two regions of the dielectric material 221. In one such example, lining sidewalls of the gate electrodes 214-1 and 214-2 with the dielectric material 221 may have the benefit of increasing the field in the device 204B. The dielectric material 221 may include any suitable dielectric material, such as a high-k dielectric material. In some examples, the dielectric material may include or more of: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In one example, the thickness 244 of the dielectric material 221 may be in a range of about 3 to 20 nanometers. In one example where the dielectric material 221 is between the first gate electrode 214-1 and the airgap 205 and between the second gate electrode 214-2 and the airgap 205, a region between the first gate electrode 214-1 and the second gate electrode 214-2 includes about 25-75% of the dielectric material 221 by cross-sectional area (e.g., the airgap occupies about 25-75% of the region by cross-sectional area).

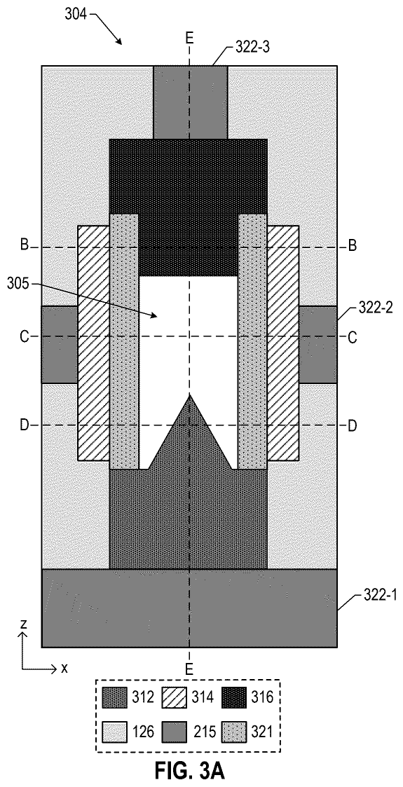

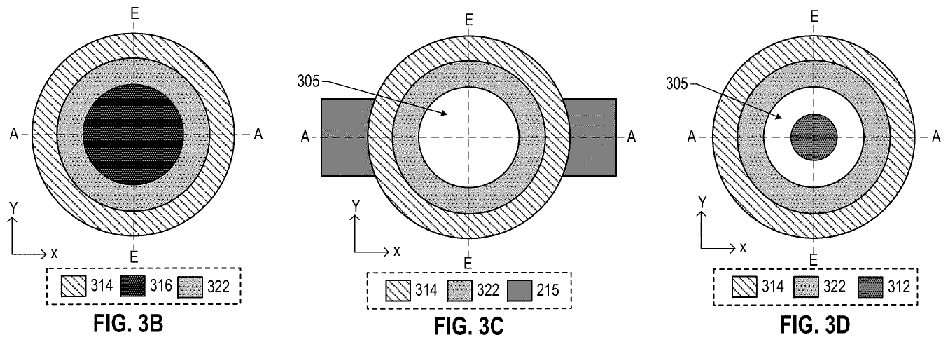

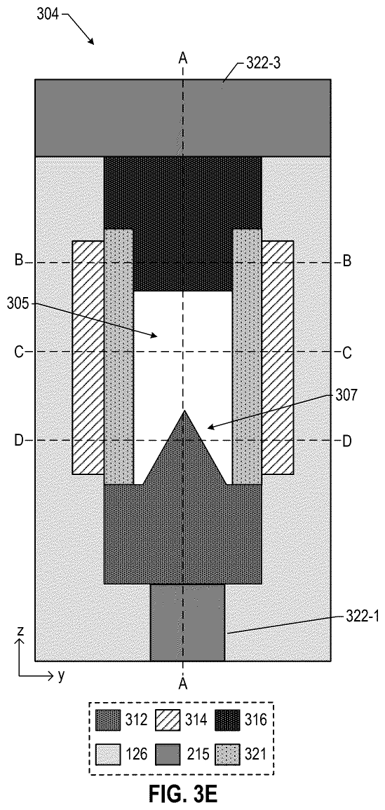

Thus, FIGS. 2A and 2B illustrate cross-sectional views of two backend field emission devices 204A and 204B. The various elements of the backend field emission devices may have different dimensions, materials, or other properties than the examples illustrated in FIGS. 2A and 2B. For example, although the backend field emission devices 204A and 204B of FIGS. 2A and 2B illustrate double-gated field emission devices, in other examples, backend field emission devices may be single-gated (e.g., with a single-gate electrode), or may have other gate arrangements. For example, FIGS. 3A-3D illustrate different cross-sectional views of a gate-all-around backend field emission device. FIG. 3A illustrates a cross-section in the x-z plane of the example coordinate system shown in FIG. 1 along a plane AA shown in the corresponding FIGS. 3B, 3C, 3D, and 3E. FIGS. 3B, 3C, and 3D illustrate cross-sections in the x-y plane along different planes labeled in FIG. 3A as planes BB, CC, and DD, respectively. FIG. 3E illustrates a cross-section in the x-z plane of the example coordinate system shown in FIG. 1 along a plane EE shown in the corresponding FIGS. 3A, 3B, 3C, and 3D.

Turning first to FIG. 3A, the backend field emission device 304 is similar to the backend field emission devices 204A and 204B in that the device 304 includes a first electrode and a second electrode over a BEOL layer, where one of the first electrode and the second electrode is an emitter element and another of the first electrode and the second electrode is a collector element. For example, the backend field emission device 304 includes an emitter electrode 312 and a collector electrode 316 aligned with and opposite the emitter electrode 312. The emitter electrode 312 may be coupled with a conductive interconnect 322-1, and the collector electrode 316 may be coupled with a conductive interconnect 322-3. The backend field emission device 304 further includes a void or airgap 305 in a plane between the emitter electrode 312 and the collector electrode 316 (e.g., in the CC plane shown in FIG. 3A), and a gate electrode material 314 in the plane between the emitter electrode 312 and the collector electrode 316. For example, the gate electrode material 314 is present in the plane CC shown in FIG. 3A. The backend field emission device 304 differs from the backend field emission devices 204A and 204B in that the gate electrode includes a continuous gate electrode material 314 surrounding at least a portion of the airgap 305. For example, FIGS. 3B-3D illustrate that the gate electrode material 314 wraps around the airgap 305, and may also wrap around a portion of the emitter electrode 312 and collector electrode 316.

Referring again to FIG. 3A, the backend field emission device 304 also includes an insulator material 322 between the gate electrode material 314 and the emitter electrode 312, between the gate electrode material 314 and the collector electrode 316, and between the gate electrode material 314 and the airgap 305. The insulator material 321 may be an example of the dielectric material 221 discussed above, and may be any suitable insulator material (e.g., a dielectric material, a high-k dielectric material, or other suitable insulator material). In one example, a continuous dielectric material (e.g., a continuous portion of the insulator material 321) surrounds at least a portion of the airgap 305, and a continuous gate electrode material 314 surrounding the continuous dielectric material. In one such example, the gate electrode material 314 may be coupled with a conductive line 322-2 that is coplanar with the gate electrode material 314 (e.g., in a plane substantially parallel to the substrate, e.g., in the x-y plane as shown in FIG. 3A). The cross-sectional view shown in FIG. 3E shows that the emitter electrode 312 has a tip portion 307 that tapers away from the pointed tip in both the x-z and y-z planes. Thus, the tip portion 307 shown in FIGS. 3A and 3E has a substantially conical shape; however, as mentioned above, the tip portion 307 may have a different shape than the examples shown (e.g., the sides of the tip portion 307 that meet at the tip may be curved and concave). FIG. 3E also depicts that the conductive interconnects 322-1 and 322-3 may be orthogonal to one another; however, in other examples, the conductive interconnects 322-1 and 322-3 that coupled with the emitter electrode 312 and 316, respectively, may be parallel, or may be or include conductive vias.

The dimensions and materials of the elements of the backend field emission device 304 may be similar to the dimensions of the corresponding backend field emission devices 204A and 204B, discussed above. For example, the distance between the tip of the emitter electrode 312 and the collector electrode 316 may be about 5 to 50 nanometers, and the emitter electrode 312 includes a pointed tip opposite the collector electrode 316, where the pointed tip may have a width in a range of about 1 to 10 nanometers, or about 1 to 6 nanometers (e.g., where the width is a dimension of the pointed tip in a plane substantially parallel to the BEOL layer). Although the example illustrated in FIGS. 3A-3E has a substantially round cross-sectional shape (e.g., as shown in FIGS. 3B-3D), in other examples, the backend field emission device 304 with a wrap-around gate may have a variety of shapes (e.g., oval, hexagonal, rectangular, etc.). Also, although the examples in both FIGS. 2A-2B and 3A-3E illustrate backend field emission devices in which the collector electrode is located in a layer above the emitter electrode, in other examples, the collector electrode may be in a layer below the emitter electrode.

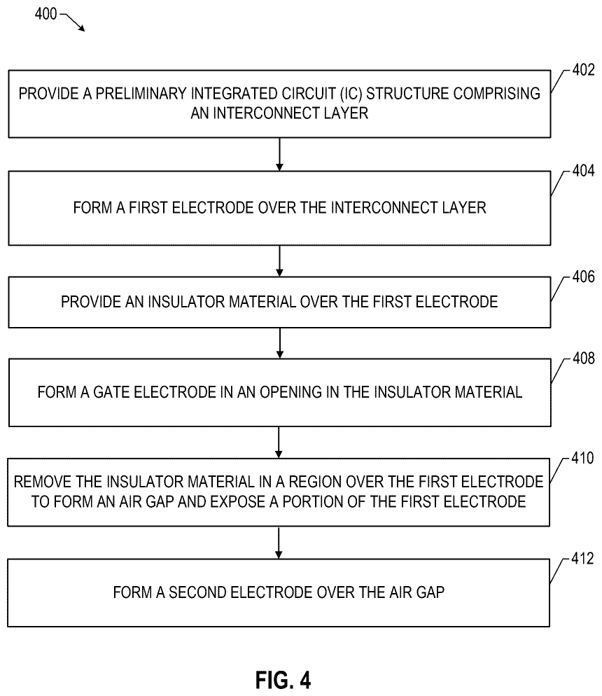

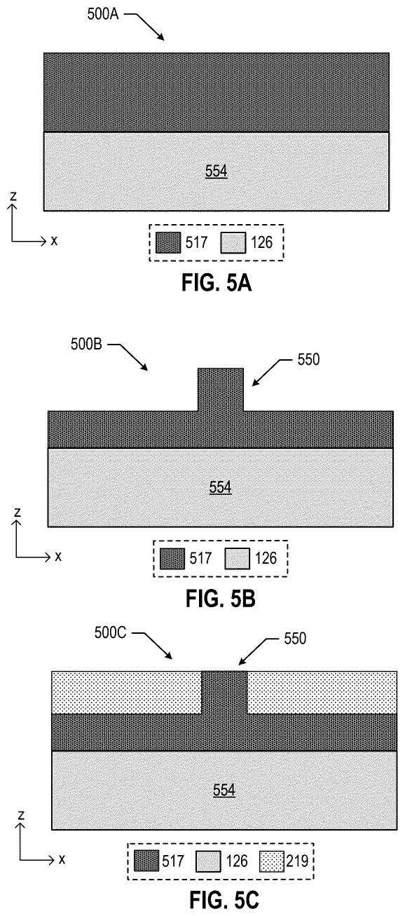

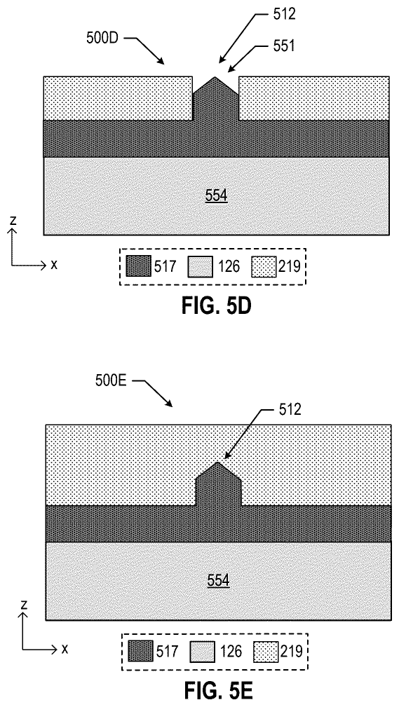

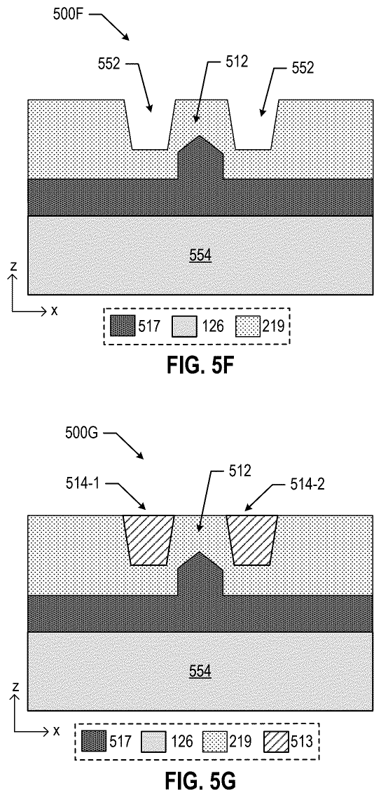

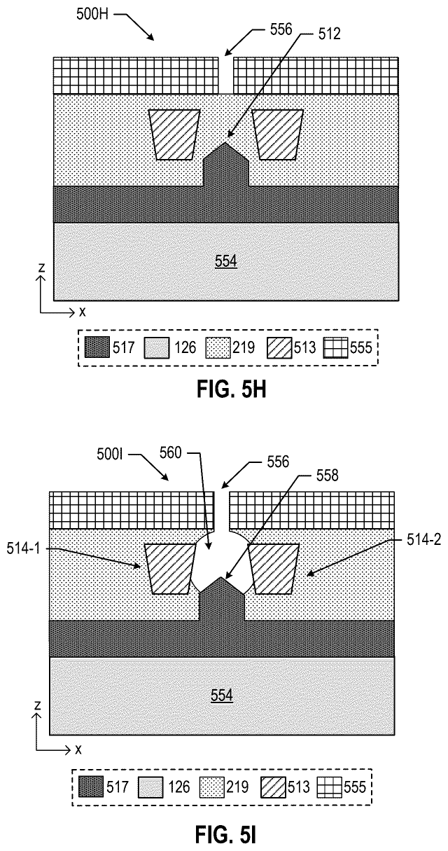

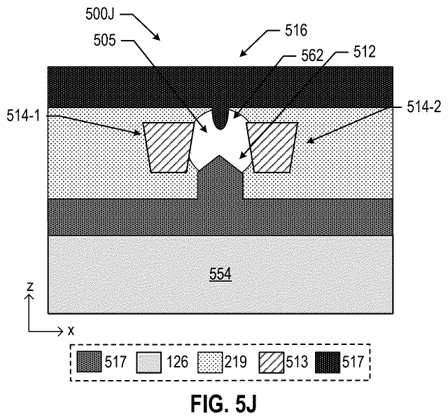

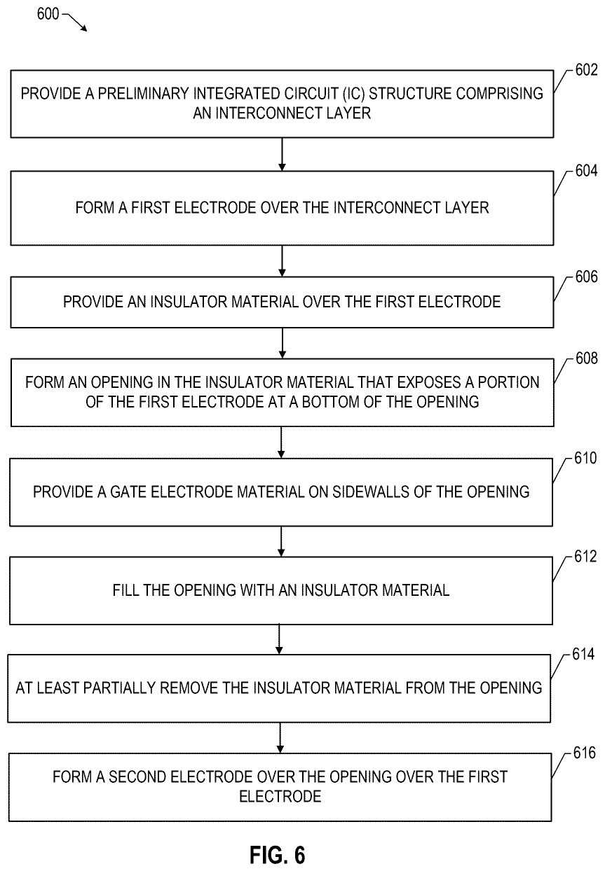

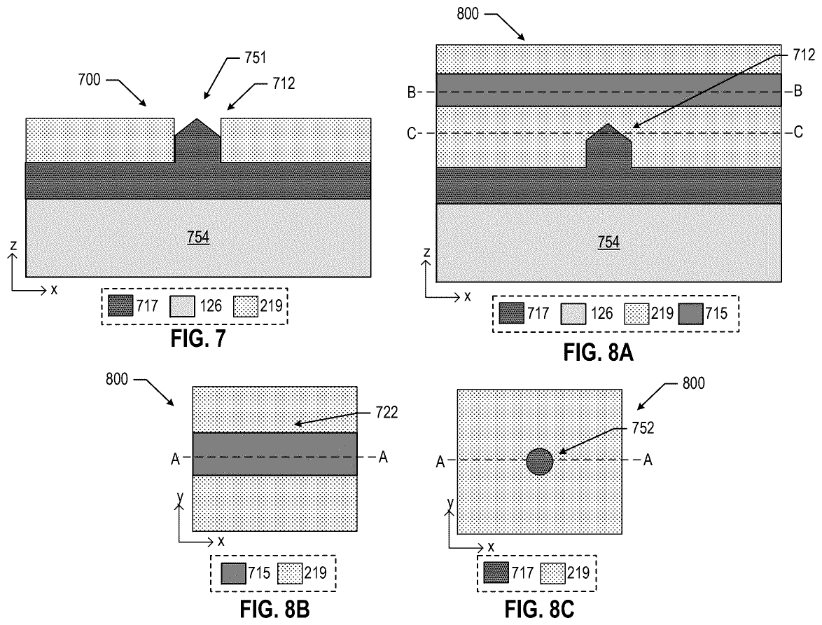

FIGS. 4 and 6 are flow diagrams of example methods 400 and 600 for fabricating IC structures including backend field emission devices. FIGS. 5A-5J provide different views at various stages in the fabrication of an example IC structure according to the method of FIG. 4, in accordance with some embodiments. FIGS. 7, 8A-8B, 9A-9B, 10A-10B, 11A-11B, 12A-12B, and 13A-13B provide different views at various stages in the fabrication of an example IC structure according to the method of FIG. 6, in accordance with some embodiments. Those figures of FIGS. 8A-8C, 9A-9C, 10A-10C, 11A-11C, 12A-12C, and 13A-13C that are labeled with a letter A (e.g., FIG. 8A) illustrate cross-sections in the x-z plane of the example coordinate system shown in FIG. 1 along a plane AA shown in corresponding figures labeled with a letter B and C (e.g., along a plane AA shown in FIGS. 8B and 8C). Those figures of FIGS. 8A-8C, 9A-9C, 10A-10C, 11A-11C, 12A-12C, and 13A-13C that are labeled with a letter B (e.g., FIG. 8B) illustrate cross-sections in the x-y plane of the example coordinate system shown in FIG. 1 along a plane BB shown in a corresponding figure labeled with a letter A (e.g., along a plane BB shown in FIG. 8A). Those figures of FIGS. 8A-8C, 9A-9C, 10A-10C, 11A-11C, 12A-12C, and 13A-13C that are labeled with a letter C (e.g., FIG. 8C) illustrate cross-sections in the x-y plane of the example coordinate system shown in FIG. 1 along a plane CC shown in a corresponding figure labeled with a letter A (e.g., along a plane CC shown in FIG. 8A). Although the operations of the methods of FIGS. 4 and 6 are illustrated once each and in a particular order, the operations may be performed in any suitable order and repeated as desired. For example, one or more operations may be performed in parallel to fabricate multiple IC structures including backend field emission devices substantially simultaneously. In another example, the operations may be performed in a different order to reflect the structure in which backend field emission devices will be implemented.

In addition, the example fabricating methods of FIGS. 4 and 6 may include other operations not specifically shown in FIGS. 4 and 6, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIGS. 4 and 6 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 4, the method 400 begins with a process 402 of providing a preliminary IC structure including an interconnect layer and a process 404 of forming a first electrode over the interconnect layer. Forming the first electrode may involve, for example, providing a conductive material over the interconnect layer, patterning the conductive material to form a protruding portion of the conductive material, and forming a pointed tip from the protruding portion of the conductive material. The IC structures 500A-500D of FIGS. 5A-5D are example resulting IC structures of the processes 402 and 404. The IC structure 500A depicts an interconnect layer 554 including the ILD 126. The interconnect layer 554 may also include conductive interconnects (e.g., conductive lines and/or conductive vias). The IC structure 500A also includes a layer of an electrically conductive material 517. The electrically conductive material 517 may include any suitable electrically conductive material for forming an emitter or collector electrode, such as any of those described above, and may be deposited using any suitable technique, such as atomic layer deposition (ALD), chemical vapor deposition (CVD), plasma enhanced CVD (PECVD), or/and physical vapor deposition (PVD) processes such as sputter.

The IC structure 500B of FIG. 5B illustrates the layer of electrically conductive material 517 after patterning (e.g., after providing a mask over the electrically conductive material 517 and etching portions of the electrically conductive material 517 through the mask). Removing portions of the electrically conductive material 517 to form a protruding portion 550 of the electrically conductive material 517 may involve any suitable etching technique, e.g., a dry etch, such as e.g., radio frequency (RF) reactive ion etch (RIE) or inductively coupled plasma (ICP) RIE. An insulator material 219 may then be provided over the electrically conductive material 517, as can be seen in the IC structure 500C of FIG. 5C. The insulator material 219 may be any suitable insulator material, such as those discussed above. The insulator material 219 may be the same as, or different from, the ILD 126. The insulator material may be deposited using any suitable deposition technique, such as ALD, CVD, plasma enhanced CVD (PECVD), or/and PVD processes such as sputter. The insulator material 219 may have been recessed to expose a top of the protruding portion 550 of the electrically conductive material 517, as shown in FIG. 5C. In other examples, the protruding portion 550 may be formed by first providing the insulator material 219, forming an opening the insulator material 219 and depositing the electrically conductive material 517 in the opening. Regardless of whether an additive or subtractive process is used, the exposed protruding portion 550 may then be etched to form a pointed tip 551, as shown in FIG. 5D. Thus, the IC structure 500D includes a first electrode 512 formed from the electrically conductive material 517. In the example illustrated in FIG. 5D, the first electrode 512 is an emitter electrode with a pointed tip.

Referring again to the method 400 of FIG. 4, the method 400 continues with a process 406 of providing an insulator material over the first electrode. The IC structure 500E of FIG. 5E is an example resulting IC structure of the process 406. The IC structure 500E includes the insulator material 219 over the first electrode 512. The insulator material 219 may be provided using any suitable technique, such as those discussed above. The example illustrated in FIG. 5E depicts the same insulator material 219 being provided over the first electrode 512 and below the first electrode 512; however, in other examples, the insulator material provided in FIG. 5C may be the same as, or different form, the insulator material provided in FIG. 5E.

The method 400 continues with a process 408 of forming a gate electrode in an opening in the insulator material. Forming the gate electrode may involve, for example, forming one or more openings in the insulator material and filling the one or more openings with an electrically conductive material. The IC structures 500F and 500G of FIGS. 5F and 5G are example resulting IC structures of the process 408. As can be seen in FIG. 5F, the IC structure 500F includes openings 552 on either side of the first electrode 512. The openings 552 may be formed with any suitable technique, such as the etching techniques discussed above. Although FIG. 5F depicts an example in which two openings 552 are formed, in other examples, a single opening or another number of openings may be formed. FIG. 5G illustrates an example IC structure 500G in which the openings 552 have been filled with an electrically conductive material 513. The electrically conductive material 513 may be any suitable electrically conductive material, e.g., any suitable gate electrode material, such as those discussed above. Thus, the IC structure 500G includes two gate electrodes 514-1 and 514-2.

The method 400 continues with a process 410 of removing the insulator material in a region over the first electrode to form an airgap and expose a portion of the first electrode. Removing the insulator material in the process 410 may involve, for example, providing a mask over the insulator material and forming an opening in the insulator material through the mask that exposes the first electrode. The IC structures 500H and 500I of FIGS. 5H and 5I are example resulting IC structures of the process 410. The IC structure 500H includes a mask 555 over the insulator material 219, where the mask 555 includes an opening 556 over the first electrode 512. The insulator material 219 may then be partially removed (e.g., evacuated) through the opening 556 in the mask 555 to form an opening 560, as shown in FIG. 5I. As can be seen in FIG. 5I, an opening 560 is formed in the insulator material 219 that exposes a portion 558 of the first electrode 512. In the example illustrated in FIG. 5I, a portion or sidewalls of each of the gate electrodes 514-1 and 514-2 is also exposed in the opening 560. The opening 560 may be formed using any suitable technique, for example, a wet etch process or other suitable etching technique, such as the techniques discussed above. Although the opening 560 shown in FIG. 5I has a rounded shape, in other examples, the opening 560 may have a substantially straight profile (e.g., sidewalls that are substantially straight as opposed to curved). A portion of the opening 560 will eventually become the airgap between the emitter electrode and collector electrode of a backend field emission device. In some examples, after forming the opening, a further insulator material, such as the dielectric material 221 discussed above with respect to FIG. 2B, may be provided on the exposed sidewalls of the gate electrodes 514-1 and 514-2 exposed in the opening 560.

The method 400 continues with a process 412 of forming a second electrode over the airgap. Forming the second electrode may involve, for example, depositing an electrically conductive material 517 over the insulator material 219 and over the opening 560. The IC structure 500J of FIG. 5J is an example resulting IC structure of the process 412, in which the mask 555 has been removed, and a second electrode 516 has been formed over an airgap 505. The electrically conductive material 517 may include any suitable electrically conductive material for forming an emitter or collector electrode, such as the collector electrode material discussed above. The electrically conductive material 517 may be provided using any suitable deposition technique, such as the techniques discussed above. In the example illustrated in FIG. 5J, the initial opening in the insulator material 219 is small enough so that as the electrically conductive material 517 is deposited on the sidewalls of the initial opening, the opening is blocked so that further electrically conductive material 517 does not fill the opening beyond the initial opening. Thus, the IC structure 500J includes a protruding portion 562 of the electrically conductive material 517 that extends towards, and is substantially aligned with, the pointed tip of the first electrode 512. In the example illustrated in FIG. 5J, the electrically conductive material 517 forms a collector electrode 516 that is substantially aligned with and opposite the emitter electrode 512, with the airgap 505 between the second electrode 516 and the first electrode 512.

FIG. 6 is a flow diagram of another method 600 of fabricating an IC structure including a backend field emission device. The method 600 begins with a process 602 of providing a preliminary IC structure including an interconnect layer and a process 604 of forming a first electrode over the interconnect layer. Forming the first electrode may involve a process similar to that discussed above with respect to the method 400, for example, providing a conductive material over the interconnect layer, patterning the conductive material to form a protruding portion of the conductive material, and forming a pointed tip from the protruding portion of the conductive material. The IC structure 700 of FIG. 7 is an example resulting IC structure of the processes 602 and 604. The IC structure 700 includes a first electrode 712 including an electrically conductive material 717 over an interconnect layer 754, where the first electrode 712 includes a pointed tip 751. The first electrode 712 may be similar to or the same as the first electrode 512, and the electrically conductive material 717 may be similar to or the same as the electrically conductive material 517 discussed above with respect to the FIGS. 5A-5D.

The method 600 continues with a process 606 of providing an insulator material over the first electrode. The IC structure 800 of FIGS. 8A-8C is an example resulting IC structure of the process 606. As can be seen in FIG. 8A, the IC structure 800 includes the insulator material 219 over the first electrode 712. The insulator material 219 may be provided using any suitable technique, such as those discussed above. The example illustrated in FIG. 8A depicts the same insulator material 219 being provided over the first electrode 712 and below the first electrode 712; however, in other examples, the insulator material provided in FIG. 7 may be the same as, or different form, the insulator material provided in FIG. 8A. As can also be seen in FIG. 8A, an electrically conductive material 715 may also be provided over the insulator material 219, and a further layer of the insulator material 219 may be provided over the electrically conductive material 715. In one such example, the electrically conductive material 715 may form a conductive interconnect that may be coupled with a coplanar gate electrode that is formed in a subsequent process. The cross-sectional view shown in FIG. 8B depicts a conductive interconnect 722 of the electrically conductive material 715, and the cross-sectional view shown in FIG. 8C depicts a tip portion 752 of the first electrode 712.

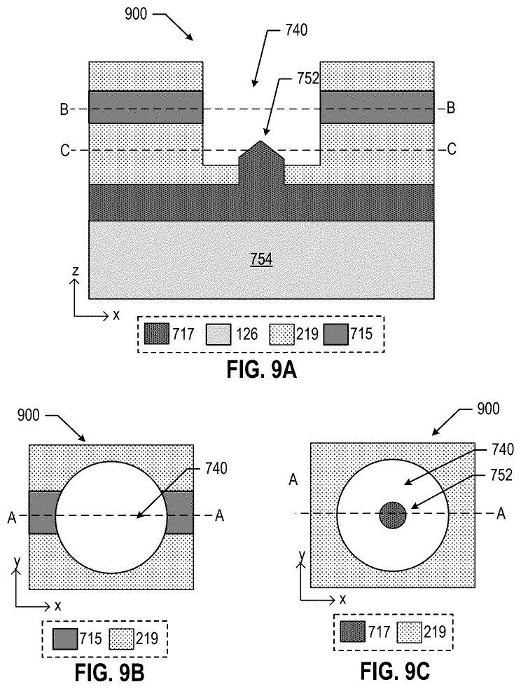

The method 600 continues with a process 608 of forming an opening in the insulator material that exposes a portion of the first electrode at a bottom of the opening. The IC structure 900 of FIGS. 9A-9C is an example resulting IC structure of the process 608. The IC structure 900 of FIGS. 9A-9C includes an opening 740 in the insulator material 219, where a portion 752 of the first electrode 712 is exposed at a bottom of the opening 740. Forming the opening may involve any suitable etching technique, such as those techniques discussed above. In the example illustrated in FIGS. 9A-9C, forming the opening 740 involves etching a layer of the insulator material 219, etching a layer of the electrically conductive material 715, and etching another layer of the insulator material 219. The example illustrated in FIGS. 9A-9C includes a substantially round opening 740; however, in other examples, an opening having a different cross-sectional shape may be formed in the insulator material 219.

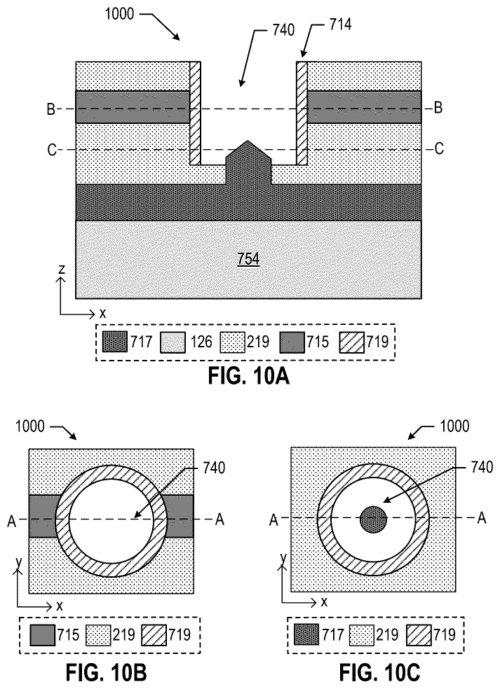

The method 600 continues with a process 610 of providing a gate electrode material on sidewalls of the opening. The IC structure 1000 of FIGS. 10A-10C is an example resulting IC structure of the process 610. The IC structure 1000 of FIGS. 10A-10C includes an electrically conductive material 719 on the sidewalls of the opening 740. As can be seen in FIGS. 10B and 10C, the electrically conductive material 719 forms a continuous portion of the electrically conductive material 719 on the sidewalls of the opening 740. The electrically conductive material 719 may be provided on the sidewalls of the opening 740 using any suitable deposition technique. In some examples, the electrically conductive material 719 may be selectively deposited on the sidewalls of the opening 740. In other examples, the electrically conductive material 719 may be deposited in other regions of the opening 740 (e.g., over the bottom of the opening 740), and later partially removed, leaving the electrically conductive material 719 only on the sidewalls of the opening 740. Thus, in the example illustrated in FIGS. FIGS. 10A-10C, the electrically conductive material 719 forms a gate electrode 714 that will eventually wrap around the structure of the resulting backend field emission device.

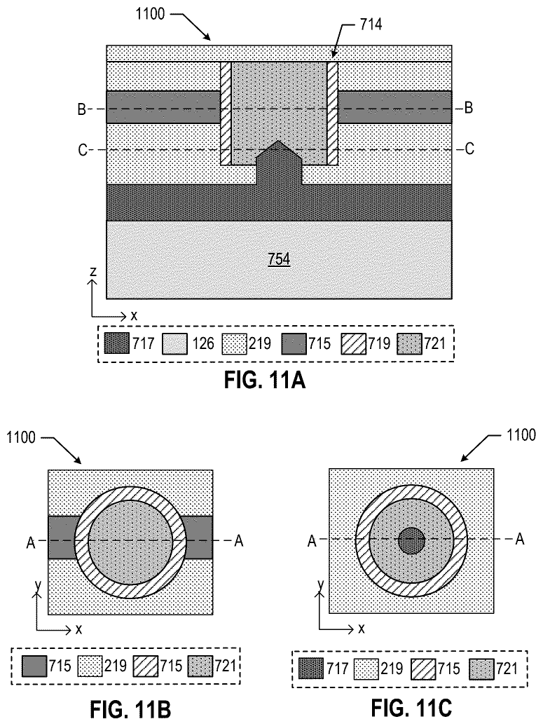

The method 600 continues with a process 612 of filling the opening with an insulator material. The IC structure 1000 of FIGS. 11A-11C is an example resulting IC structure of the process 612. The IC structure 1100 of FIGS. 11A-11C includes an insulator material 721 filling the opening 740. The insulator material 721 may be provided in accordance with any suitable deposition technique, such as those discussed above. In various examples, the insulator material 721 will be entirely removed in a subsequent process, while in other examples, portions of the insulator material 721 may remain on the sidewalls of the opening over the electrically conductive material 719. In some examples, the insulator material 721 may be an example of the dielectric material 221 of FIG. 2B. In other examples, the insulator material 721 may be any suitable insulator material for use as a sacrificial material. In the example illustrated in FIG. 11A, a layer of the insulator material 219 may be provided over the insulator material 721 (e.g., to provide additional isolation between the gate electrode 714 and the electrode to be formed over the IC structure 1100).

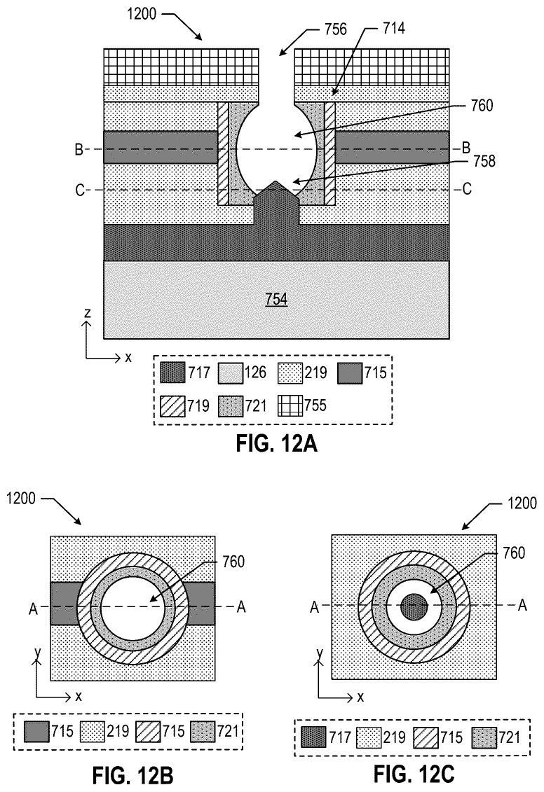

The method 600 continues with a process 614 of at least partially removing the insulator material from the opening. At least partially removing the insulator material in the process 614 may involve, for example, providing a mask over the insulator material and forming an opening in the insulator material through the mask that exposes the first electrode. The IC structure 1200 of FIGS. 12A-12C is an example resulting IC structure of the process 614. The IC structure 1200 includes a mask 755 over the insulator material 721 (as well as over the insulator material 219), where the mask 755 includes an opening 756 over the insulator material 721 and over the first electrode 712. The insulator material 721 may then be partially removed (e.g., evacuated) through the opening 756 in the mask 755 to form an opening 760, as shown in FIGS. 12A-12C. As can be seen in FIGS. 12A-12C, the opening 760 formed in the insulator material 721 exposes a portion 758 of the first electrode 712. In the example illustrated in FIG. 12A-12C, the insulator material 721 is only partially removed, and therefore a layer of the insulator material 721 lines the sidewalls of the gate electrode 714. In other examples, the insulator material 721 may be completely removed to expose sidewalls of the gate electrode 714 in the opening 760. The opening 760 may be formed using any suitable technique, for example, a wet etch process or other suitable etching technique, such as the techniques discussed above. Although the opening 760 shown in FIG. 12A-12C has a rounded shape, in other examples, the opening 760 may have a substantially straight profile. In an example in which the opening 760 has a rounded shape, the thickness of the insulator material 721 lining the gate electrode 714 may be different along different planes, as can be seen in FIGS. 12B and 12C (e.g., the insulator material 721 has a greater thickness in the cross-section shown in FIG. 12C and a smaller thickness in the cross-section shown in FIG. 12B). A portion of the opening 760 will eventually become the airgap between the emitter electrode and collector electrode of a backend field emission device.

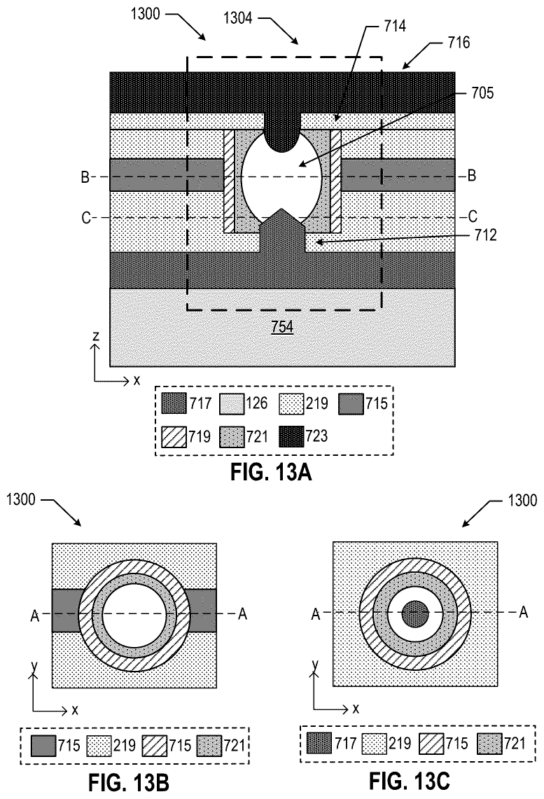

The method 600 continues with a process 616 of forming a second electrode over the opening over the first electrode. The IC structure 1300 of FIGS. 13A-13C is an example resulting IC structure of the process 616. The IC structure 1300 of FIGS. 13A-13C includes an electrically conductive material 723 over an airgap 705, forming a second electrode 716. Forming the second electrode 716 may involve a similar process to the process 412 of FIG. 4 (e.g., depositing the electrically conductive material 723 over the insulator material 219 and partially into the initial opening of the opening 760). In the example illustrated in FIGS. 13A-13C, the second electrode 716 may be the collector electrode, which is over and aligned with an emitter electrode (e.g., the electrode 712). Thus, the IC structure 1300 includes a backend field emission device with a gate electrode material that wraps around an airgap 705 between a collector and emitter electrodes.

Thus, FIGS. 4 and 6 illustrate methods 400 and 600 for fabricating an IC structure including backend field emission devices. Performing the methods 400 or 600 may result in several features in the final IC structure that are characteristic of the use of the methods 400 or 600. For example, one such feature is illustrated in the IC structure 500J shown in FIG. 5J, in which a field emission device includes a first electrode (e.g., the emitter electrode 512), a second electrode (e.g., the collector electrode 516), an airgap 505 between the emitter electrode 512 and the collector electrode 516, and a third electrode (e.g., the gate electrodes 514-1 and 514-2) between the first electrode and the second electrode and coplanar with the airgap 505. Another such feature is illustrated in the IC structure shown in FIGS. 13A-13C, in which a field emission device 1304 includes a gate electrode 714 that includes a continuous portion of an electrically conductive material 719 that surrounds the airgap 705. Including backend field emission devices in an IC may enable mitigating noise issues, which may be especially pronounced at low temperatures.

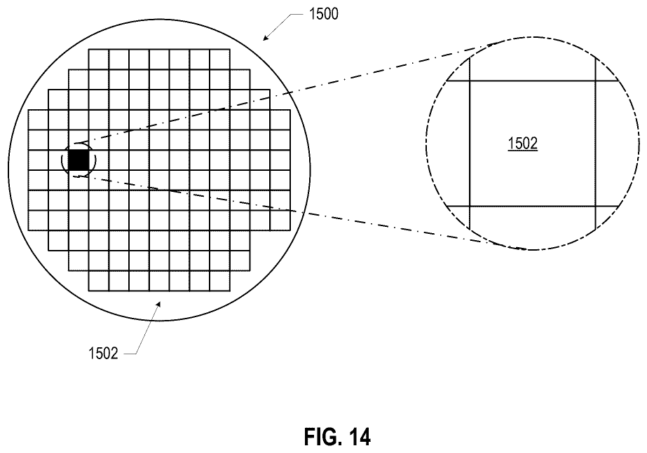

IC structures including backend field emission devices in accordance with techniques described herein may be included in any suitable electronic component or electronic device. FIGS. 14-17 illustrate various examples of apparatuses that may include one or more of the IC structures with backend field emission devices disclosed herein.

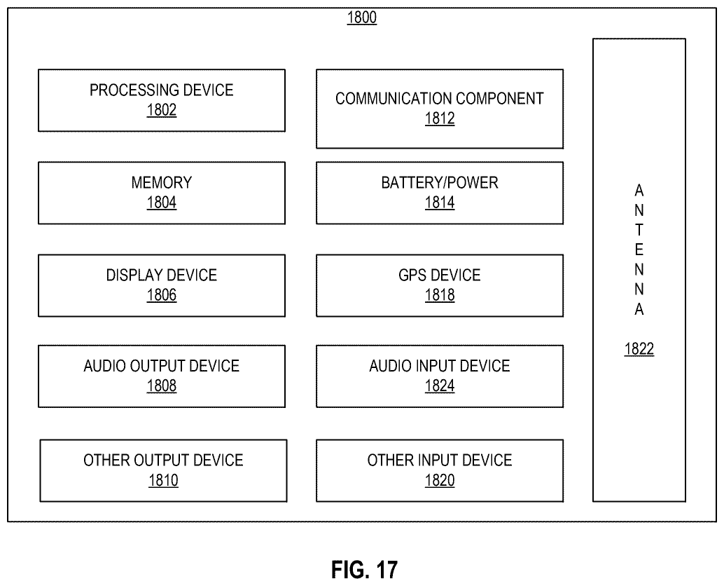

FIG. 14 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 17) or other logic that is configured to store information in the memory devices or execute instructions stored in the memory array.

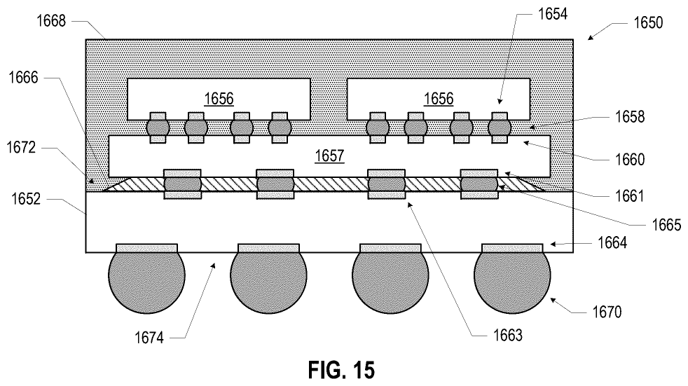

FIG. 15 is a side, cross-sectional view of an example IC package 1650 that may include one or more IC structures with backend field emission devices in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 15 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 15 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

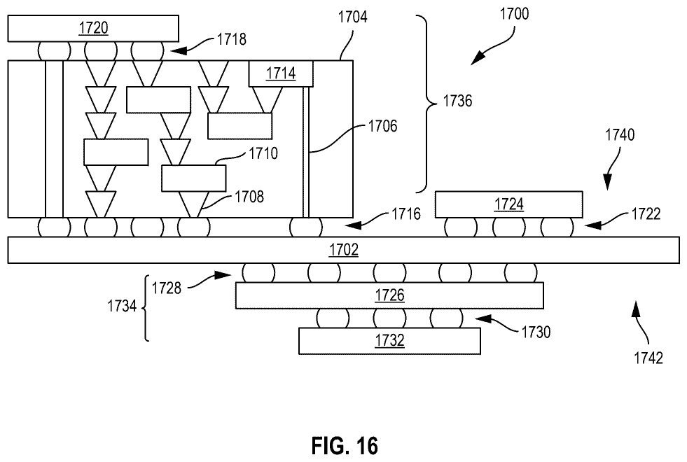

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 15 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 16.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 15 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package.

Although two dies 1656 are illustrated in the IC package 1650 of FIG. 15, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 16 is a side, cross-sectional view of an IC device assembly 1700 that may include one or more IC packages or other electronic components (e.g., a die) including one or more IC structures with backend field emission devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 15 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 16 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 16), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 16, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 14), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 16, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 16 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 17 is a block diagram of an example electrical device 1800 that may include one or more IC structures with backend field emission devices in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 17 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 17, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a device region; a first interconnect layer over the device region, where the first interconnect layer includes a first conductive interconnect; a second interconnect layer over the first interconnect layer, where the second interconnect layer includes a second conductive interconnect; and a field emission device between the first interconnect layer and the second interconnect layer, where the field emission device includes a first electrode coupled with the first conductive interconnect, a second electrode coupled with the second conductive interconnect, an airgap between the first electrode and the second electrode, and a third electrode between the first electrode and the second electrode and coplanar with the airgap.

Example 2 provides the IC structure of example 1, where: one of the first electrode and the second electrode is an emitter electrode, and another of the first electrode and the second electrode is a collector electrode, the emitter electrode includes a tip portion opposite the collector electrode, where the tip portion is a closest portion of the emitter electrode to the collector electrode, and where the tip portion has a width, the width is in a range of about 1 to 10 nanometers, and the width is a dimension of the tip portion in a plane substantially parallel to the device region.

Example 3 provides the IC structure of example 2, where: the width is a first width, the collector electrode includes a portion closest to the tip portion, the portion has a second width, where the second width is a second dimension of the portion in a second plane substantially parallel to the device region, and the second width is in a range of about 0.5 to 10 times the first width.

Example 4 provides the IC structure of any one of examples 2-3, where: in a cross-section, the tip portion includes a first side and a second side that meet at a tip (e.g., pointed tip), the tip is a portion of the emitter electrode closest to the collector electrode, the first side is at an angle relative to the second side, and the angle is in a range of about 20-80 degrees.

Example 5 provides the IC structure of any one of examples 1-4, where: a distance between the first electrode and the second electrode is in a range of about 5 to 50 nanometers.

Example 6 provides the IC structure of any one of examples 1-5, where the third electrode is a first gate electrode, and where the IC structure further includes a second gate electrode coplanar with the first gate electrode, where the airgap is between the first gate electrode and the second gate electrode.

Example 7 provides the IC structure of any one of examples 1-5, where: the third electrode includes a continuous gate electrode material surrounding at least a portion of the airgap.

Example 8 provides the IC structure of any one of examples 1-7, further including an insulator material between the first electrode and the third electrode, and between the second electrode and the third electrode.

Example 9 provides the IC structure of example 8, where: a portion of the insulator material between the first electrode and the third electrode has a thickness in a range of 3 to 20 nanometers, and the thickness is a dimension of the insulator material in a plane substantially orthogonal to the device region.

Example 10 provides the IC structure of any one of examples 1-9, further including a dielectric material between the third electrode and the airgap.

Example 11 provides the IC structure of example 10, where: the dielectric material includes one or more of: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Example 12 provides the IC structure of any one of examples 10-11, where the third electrode is a first gate electrode, and where the IC structure further includes a second gate electrode coplanar with the first gate electrode, where: the dielectric material is between the first gate electrode and the airgap and between the second gate electrode and the airgap, and a region between the first gate electrode and the second gate electrode includes about 25-75% of the dielectric material by cross-sectional area.

Example 13 provides the IC structure of any one of examples 1-5 and 7-11, where: a continuous dielectric material surrounds at least a portion of the airgap, and the third electrode includes a continuous gate electrode material surrounding the continuous dielectric material.

Example 14 provides the IC structure of any one of examples 1-13, where: the first electrode includes a first electrically conductive material with a first work function, the second electrode includes a second electrically conductive material with a second work function, and a difference between the first work function and the second work function is in a range of 0.2 to 2 eV.

Example 15 provides the IC structure of example 14, where: the first electrically conductive material includes one or more of: ruthenium, palladium, platinum, cobalt, nickel, a conductive metal oxide (e.g., ruthenium oxide), titanium nitride, and tungsten, and the second electrically conductive material includes one or more of: hafnium, zirconium, titanium, tantalum, aluminum, a conductive metal carbide (e.g., hafnium carbide, zirconium carbide, titanium carbide, tantalum carbide, and aluminum carbide), and molybdenum.

Example 16 provides an IC structure, including a BEOL layer; a first electrode and a second electrode over the BEOL layer, where one of the first electrode and the second electrode is an emitter element and another of the first electrode and the second electrode is a collector element; a void in a plane between the first electrode and the second electrode; a gate electrode material in the plane between the first electrode and the second electrode; and an insulator material between the gate electrode material and the first electrode, and between the gate electrode material and the second electrode.

Example 17 provides the IC structure of example 16, where: the plane is a first plane, the emitter element includes a pointed tip opposite the collector element, where the pointed tip has a width in a range of about 1 to 6 nanometers, and the width is a dimension of the pointed tip in a second plane substantially parallel to the BEOL layer.

Example 18 provides the IC structure of any one of examples 1-9, further including a high-k dielectric material between the gate electrode material and the void.

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a preliminary IC structure including an interconnect layer; forming a first electrode over the interconnect layer; providing an insulator material over the first electrode; forming a gate electrode in an opening in the insulator material; providing the insulator material over the gate electrode; removing the insulator material in a region over the first electrode, where removal of the insulator material in the region exposes a portion of the first electrode; and forming a second electrode over an airgap over the first electrode.

Example 36 provides the method of example 35, where: the first electrode is an emitter electrode, and forming the emitter electrode includes providing a conductive material over the interconnect layer, and forming a pointed tip from the conductive material.

Example 37 provides the method of example 36, further including after providing the conductive material: patterning the conductive material to form a protruding portion of the conductive material, where the pointed tip is formed from the protruding portion.

Example 38 provides the method of any one of examples 35-37, where: the opening is a first opening and the conductive material is a first conductive material, and forming the gate electrode further includes forming the first opening and a second opening on either side of the pointed tip, and providing a second conductive material in the first opening and the second opening.

Example 39 provides the method of any one of examples 35-38, where: removing the insulator material in the region includes providing a mask over the gate electrode, where the mask includes a first opening over the first electrode, etching (e.g., with a wet etch process) the insulator material through the first opening in the mask to form a second opening in the insulator material and expose a portion of the first electrode.

Example 40 provides the method of example 39, where: forming a second electrode includes providing a conductive material in the second opening.

Example 41 provides the method of example 39, further including providing a dielectric material on sidewalls of the second opening in a plane with the gate electrode.

Example 42 provides a method of fabricating an IC structure, the method including providing a preliminary IC structure including an interconnect layer; forming a first electrode over the interconnect layer; provide a first insulator material over the first electrode; forming an opening in the insulator material that exposes a portion of the first electrode at a bottom of the opening; providing a gate electrode material on sidewalls of the opening; filling the opening with a second insulator material; at least partially removing the second insulator material from the opening; and forming a second electrode over an airgap over the first electrode.

Example 43 provides the method of example 42, where: the first electrode is an emitter electrode, and forming the emitter electrode includes providing a conductive material over the interconnect layer, prior to forming the gate electrode, recessing the insulator material to expose a portion of the conductive material, and forming a pointed tip from the exposed conductive material.

Example 44 provides the method of example 43, further including after providing the conductive material: patterning the conductive material to form a protruding portion of the conductive material, where the pointed tip is formed from the protruding portion.

Example 45 provides the method of any one of examples 42-44, where: forming the opening includes forming a substantially the opening with a substantially round cross-sectional shape.

Example 46 provides the method of any one of examples 42-45, where: at least partially removing the second insulator material from the opening includes partially removing the second insulator material to expose the portion of the first electrode at a bottom of the opening without completely removing the second insulator material on the sidewalls.

Example 47 provides the method of any one of examples 42-46, where: forming a second electrode includes providing a conductive material in the second opening.

Example 48 provides a method according to any one of examples 35-47, where the IC structure is an IC structure according to any one of the preceding examples.

Example 49 provides a process of making an IC structure, the process including providing a preliminary IC structure including an interconnect layer; forming a first electrode over the interconnect layer; providing an insulator material over the first electrode; forming a gate electrode in an opening in the insulator material; providing the insulator material over the gate electrode; removing the insulator material in a region over the first electrode, where removal of the insulator material in the region exposes a portion of the first electrode; and forming a second electrode over an airgap over the first electrode.

Example 50 provides the process of example 49, where the process is in accordance with any of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a device region;
a first interconnect layer over the device region, wherein the first interconnect layer comprises a first conductive interconnect;
a second interconnect layer over the first interconnect layer, wherein the second interconnect layer comprises a second conductive interconnect; and
a field emission device between the first interconnect layer and the second interconnect layer, wherein the field emission device comprises:
a first electrode coupled with the first conductive interconnect,
a second electrode coupled with the second conductive interconnect,
an airgap between the first electrode and the second electrode, and
a third electrode between the first electrode and the second electrode and coplanar with the airgap.

2. The IC structure of claim 1, wherein:
one of the first electrode and the second electrode is an emitter electrode, and another of the first electrode and the second electrode is a collector electrode,
the emitter electrode comprises a tip portion, wherein the tip portion is a closest portion of the emitter electrode to the collector electrode, and wherein the tip portion has a width,
the width is in a range of about 1 to 10 nanometers, and
the width is a dimension of the tip portion in a plane substantially parallel to the device region.

3. The IC structure of claim 2, wherein:
the width is a first width, the dimension is a first dimension, and the plane is a first plane,
the collector electrode comprises a portion closest to the tip portion,
the portion has a second width, wherein the second width is a second dimension of the portion in a second plane substantially parallel to the device region, and
the second width is in a range of about 0.5 to 10 times the first width.

4. The IC structure of claim 2, wherein:
in a cross-section, the tip portion comprises a first side and a second side that meet at a tip,
the tip is a portion of the emitter electrode closest to the collector electrode,
the first side is at an angle relative to the second side, and
the angle is in a range of about 20-80 degrees.

5. The IC structure of claim 1, wherein:
a distance between the first electrode and the second electrode is in a range of about 5 to 50 nanometers.

6. The IC structure of claim 1, wherein the third electrode is a first gate electrode, and wherein the IC structure further comprises:
a second gate electrode coplanar with the first gate electrode, wherein the airgap is between the first gate electrode and the second gate electrode.

7. The IC structure of claim 1, wherein:
the third electrode comprises a continuous gate electrode material surrounding at least a portion of the airgap.

8. The IC structure of claim 1, further comprising:
an insulator material between the first electrode and the third electrode, and between the second electrode and the third electrode.

9. The IC structure of claim 8, wherein:
a portion of the insulator material between the first electrode and the third electrode has a thickness in a range of 3 to 20 nanometers, and
the thickness is a dimension of the insulator material in a plane substantially orthogonal to the device region.

10. The IC structure of claim 1, further comprising:
a dielectric material between the third electrode and the airgap.

11. The IC structure of claim 10, wherein:
the dielectric material comprises one or more of:
hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

12. The IC structure of claim 10, wherein the third electrode is a first gate electrode, and wherein the IC structure further comprises:
a second gate electrode coplanar with the first gate electrode, wherein:
the dielectric material is between the first gate electrode and the airgap and between the second gate electrode and the airgap, and
a region between the first gate electrode and the second gate electrode includes about 25-75% of the dielectric material by cross-sectional area.

13. The IC structure of claim 1, wherein:
a continuous dielectric material surrounds at least a portion of the airgap, and
the third electrode comprises a continuous gate electrode material surrounding the continuous dielectric material.

14. The IC structure of claim 1, wherein:
the first electrode comprises a first electrically conductive material with a first work function,
the second electrode comprises a second electrically conductive material with a second work function, and
a difference between the first work function and the second work function is in a range of 0.2 to 2 eV.

15. The IC structure of claim 14, wherein:
the first electrically conductive material comprises one or more of:
ruthenium, palladium, platinum, cobalt, nickel, a conductive metal oxide, titanium nitride, and tungsten, and
the second electrically conductive material comprises one or more of:
hafnium, zirconium, titanium, tantalum, aluminum, a conductive metal carbide, and molybdenum.

16. An integrated circuit (IC) structure, comprising:
a back-end of line (BEOL) layer;
a first electrode and a second electrode over the BEOL layer, wherein one of the first electrode and the second electrode is an emitter and another of the first electrode and the second electrode is a collector;
a void in a plane between the first electrode and the second electrode;
a gate electrode material in the plane between the first electrode and the second electrode; and
an insulator material between the gate electrode material and the first electrode, and between the gate electrode material and the second electrode.

17. The IC structure of claim 16, wherein:
the plane is a first plane,
the emitter comprises a pointed tip opposite the collector, wherein the pointed tip has a width in a range of about 1 to 6 nanometers, and
the width is a dimension of the pointed tip in a second plane substantially parallel to the BEOL layer.

18. The IC structure of claim 16, further comprising:
a high-k dielectric material between the gate electrode material and the void.

19. A method of fabricating an integrated circuit (IC) structure, the method comprising:
providing a preliminary IC structure comprising an interconnect layer;
forming a first electrode over the interconnect layer;
providing an insulator material over the first electrode;
forming a gate electrode in an opening in the insulator material;
providing the insulator material over the gate electrode;
removing the insulator material in a region over the first electrode, wherein removal of the insulator material in the region exposes a portion of the first electrode; and
forming a second electrode over an airgap over the first electrode.

20. The method of claim 19, wherein:
the first electrode is an emitter electrode, and forming the emitter electrode comprises:
providing a conductive material over the interconnect layer, and forming a pointed tip from the conductive material.
